(19) United States
(12) Patent Application Publication
(10) Pub. No.: US 2009/0183364 A1
(43) Pub. Date: Jul. 23, 2009

(54) METHOD OF CONNECTING A SERIES OF INTEGRATED DEVICES UTILIZING FLEXIBLE CIRCUITS IN A SEMI-STACKING CONFIGURATION

(75) Inventors: Gerald K. Bartley, Rochester, MN (US); Darryl J. Becker, Rochester, MN (US); Paul E. Dahlen, Rochester, MN (US); Philip R. Germann, Rochester, MN (US); Andrew B. Maki, Rochester, MN (US); Mark O. Maxson, Mantorville, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/016,261

(22) Filed: Jan. 18, 2008

(51) Int. Cl. H05K 3/30

(52) U.S. Cl. 29/832

(57) ABSTRACT

A method of serially connecting devices utilizing flexible circuits in a semi-stacking configuration includes positioning a first flexible circuit on a carrier, the first flexible circuit includes a bottom surface and a top surface, a portion of the bottom surface is mounted to the carrier while another portion of the bottom surface is elevated at a first angle with respect to the carrier; coupling a first device on a portion of the top surface of the first flexible circuit, the first device being elevated at the first angle; positioning a second flexible circuit on the carrier, the second flexible circuit having an upper surface and a lower surface, a portion of the lower surface is mounted to the carrier while another portion of the lower surface is elevated at a second angle with respect to the carrier and overlapped over a top surface portion of the first device; and coupling a second device on a portion of the upper surface of the second flexible circuit, the second device being elevated at the second angle.

### BACKGROUND OF THE INVENTION

1. Field of the Invention

This invention relates to a semi-stackable system, and particularly to a method of connecting a series of integrated devices utilizing flexible circuits in a semi-stacking configuration.

2. Description of Background

The stacking of higher power integrated devices (e.g., memory devices) usually introduces issues such as, the removal of heat from these devices in addition to unique interconnect challenges. There are many known solutions to stacking memory devices, each involving non-standard interconnecting methods.

The prior art contains several examples where flexible circuits have been used to form these interconnects. However, when these memory devices have higher power dissipation requirements, many of these stacking methods are limited. For example, most stacking techniques include stacking the memory devices over a flexible material in a vertical configuration, which does not account for temperature associated with higher power devices. In other words, vertical stacking for higher power devices makes it difficult for heat to escape the stack easily.

Other methods include placing the memory devices over a flexible material in a horizontal configuration, where the memory devices are spaced apart and serially connected over the flexible material. However, such a configuration minimizes space on the flexible material, thereby reducing the number of memory devices mounted over the flexible material.

In sum, chip stacking is implemented as an “all-or-nothing” technique—the chips are either stacked, or laid flat on a multi-chip module (MCM) or printed circuit board (PCB).

### SUMMARY OF THE INVENTION

The shortcomings of the prior art are overcome and additional advantages are provided through the provision of a method of connecting a series of integrated devices utilizing flexible circuits in a semi-stacking configuration, the method comprising: positioning a first flexible circuit on a carrier, the first flexible circuit including a bottom surface and a top surface, a portion of the bottom surface mounted to the carrier while another portion of the bottom surface is elevated at a first angle with respect to the carrier; coupling a first integrated device on a portion of the top surface of the first flexible circuit, the first integrated device being elevated at the first angle; positioning a second flexible circuit on the carrier, the second flexible circuit having an upper surface and a lower surface, a portion of the lower surface is mounted to the carrier while another portion of the lower surface is elevated at a second angle with respect to the carrier and overlaid over a top surface portion of the first integrated device; and coupling a second integrated device on a portion of the upper surface of the second flexible circuit, the second integrated device being elevated at the second angle.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### TECHNICAL EFFECTS

As a result of the summarized invention, technically we have achieved a solution for connecting a series of integrated devices utilizing flexible circuits in a semi-stacking configuration.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a schematic diagram of one of a plurality of assemblies positioned on a carrier where each of the plurality of assemblies includes a single packaged memory device on a flexible circuit in accordance with one exemplary embodiment of the present invention;

FIG. 2 illustrates a system with the plurality of assemblies positioned on the carrier in accordance with one exemplary embodiment of the present invention;

FIG. 3 illustrates the system with the plurality of assemblies each having a heat sink device in accordance with one exemplary embodiment of the present invention;

FIG. 4 illustrates a plurality of fins of each heat sink device correspondingly mounted on the plurality of assemblies being tied together above the components of each of the plurality of assemblies in accordance with one exemplary embodiment of the present invention;

FIG. 5 illustrates the plurality of fins of each heat sink device correspondingly mounted on the plurality of assemblies being tied together on the side of the components of each of the plurality of assemblies in accordance with one exemplary embodiment of the present invention;

FIG. 6 illustrates the system with the plurality of assemblies having a single continuous heat sink device in accordance with one exemplary embodiment of the present invention;

FIG. 7 illustrates the system with the plurality of assemblies each being bent at an angle in accordance with one exemplary embodiment of the present invention; and

FIG. 8 illustrates a flow diagram of a method of connecting a series of integrated devices utilizing flexible circuits in a semi-stacking configuration in accordance with one exemplary embodiment of the present invention.

The detailed description explains the preferred embodiments of the invention, together with advantages and features, by way of example with reference to the drawings.

### DETAILED DESCRIPTION OF THE INVENTION

The present invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known or conventional components and processing techniques are omitted so as to not necessarily obscure the present invention in detail. The examples used herein are intended merely to facilitate an understanding of ways in which the invention may be practiced and to further enable those of skill in the art to practice the invention. Accordingly, the examples should not be construed as limiting the scope of the invention.

The inventors herein have recognized that taking a plurality of memory devices, such as a package extended dynamic range (XDR) memory component, and correspondingly mounting the plurality of memory devices on individually flexible circuit carriers that can then be assembled on the next packaging level, such as a multi-chip module (MCM) or a printed circuit board (PCB), and connecting the flexible circuit carriers and the next packaging level in a manner that allows each of the plurality of memory devices to be assembled over a smaller area of the next packaging level by overlapping the devices, similar to shingles overlapping and stacking on a roof, will permit heat from the devices to escape efficiently. In other words, such a configuration permits a portion of each of the plurality of memory devices to be exposed, thereby allowing heat removal in the form of airflow over the devices or different configurations of heat sinks (continuous or individual) attached to the devices. The inventors herein have further recognized that such a configuration provides for a tighter pitch layout. In other words, this configuration allows more integrated devices (e.g., memory device) to be assembled over a smaller area of the carrier (e.g., PCB) while allowing the integrated devices to cool efficiently.

Exemplary embodiments of a semi-stackable system and a method of assembling the same in accordance with the present invention will now be described with reference to the drawings. An exemplary embodiment of a method for connecting a series of integrated devices utilizing flexible circuits in a semi-stacking configuration is provided comprising: positioning a first flexible circuit on a carrier, the first flexible circuit includes a bottom surface and a top surface, a portion of the bottom surface is mounted to the carrier while another portion of the bottom surface is elevated at a first angle with respect to the carrier; coupling a first integrated device on a portion of the top surface of the first flexible circuit, the first integrated device being elevated at the first angle; positioning a second flexible circuit on the carrier, the second flexible circuit having an upper surface and a lower surface, a portion of the lower surface is mounted to the carrier while another portion of the lower surface is elevated at a second angle with respect to the carrier and overlaid over a top surface portion of the first integrated device; and coupling a second integrated device on a portion of the upper surface of the second flexible circuit, the second integrated device being elevated at the second angle.

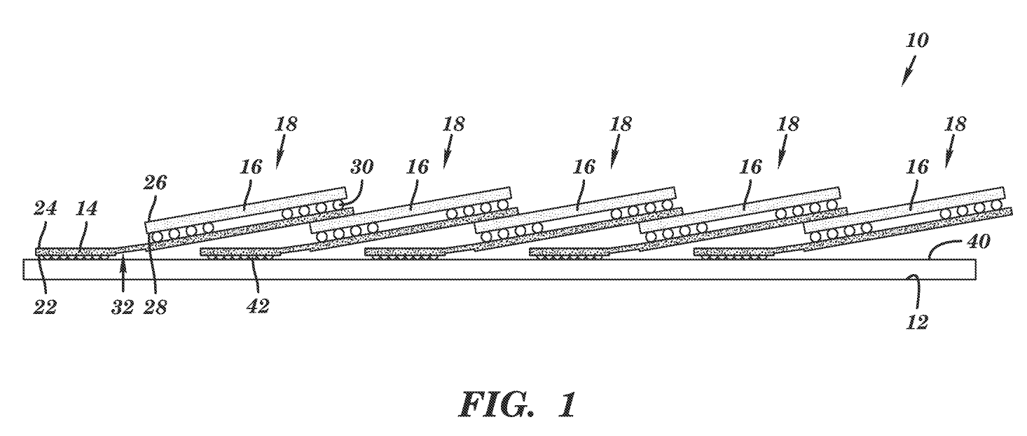

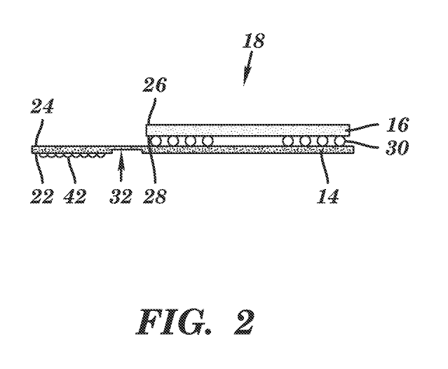

Now turning to a discussion of a semi-stackable system in accordance with one exemplary embodiment of the present invention. FIG. 1 illustrates a semi-stackable system 10 in accordance with one exemplary embodiment of the present invention. The system comprises a carrier or carrier package 12, flexible circuits 14, and single packaged integrated devices 16. The flexible circuits 14 are individually assembled on the carrier package 12. The single packaged integrated devices 16 are correspondingly mounted on the flexible circuits 14 forming an assembly 18 as shown in FIG. 2. In one exemplary embodiment, the integrated devices 16 are serially connected through the carrier package 12. The connection between the flexible circuits 14 and the carrier package 12 allows the integrated devices 16, which are mounted correspondingly to the flexible circuits 14, to be assembled in a smaller area of the carrier package 12 by overlapping the devices in a single-like configuration, which will become more apparent with the discussion below.

For ease of discussion, a schematic of a single packaged integrated device 16 mounted on a flexible circuit 14, and more specifically an assembly 18 is illustrated in FIG. 2 and described. However, it should be understood that each of the integrated devices 16 in FIG. 1 could similarly be mounted correspondingly to the flexible circuits 14 shown in FIG. 1 in accordance with one exemplary embodiment, thus forming more than one assembly 18 over the carrier package 12. In one exemplary embodiment, the single packaged integrated device 16 is a memory device, such as a Dynamic Random Access Memory (DRAM). Of course, other conventional single packaged integrated devices of varying types and sizes (e.g., controller devices, central processing units, etc.) can be used in exemplary embodiments of the present invention and should not be limited to the example set forth above.

In accordance with one embodiment, the flexible circuit 14 may be fabricated from any type of flexible, conductive material such as, for example, a flexible laminate comprising a metal cladding material adhered to a dielectric substrate, such as, for example, a polyimide film or the like. Of course, other suitable dielectric substrates or equivalents thereof could be used to construct flexible circuit 14 in accordance with exemplary embodiments of the present invention. The flexible laminate is configured to freely form over or conform to non-planar surfaces, structures or otherwise. The flexible laminate may be of any thickness and length depending on the application. In one embodiment, the fabrication and configuration of the flexible circuit 14 are a polyimide film with conductive traces formed along one or both sides of the flexible circuit 14.

In accordance with one embodiment, the flexible circuit 14 has a bottom surface 22 and a top surface 24. In one embodiment, the single packaged integrated device 16 has a first side 26 and a second side 28, where the second side 28 is coupled to the conductive traces (not shown) located on the top surface 24 of the flexible circuit 14. Conventional means for securing the single packaged integrated device 16 to the conductive traces on the top surface 24 of the flexible circuit 14 may include, for example, solder balls, conductive or conductor-filled adhesive elements, copper pads, or the like. Such conventional means may be part of or separate from the integrated device 16 and/or flexible circuit 14. For illustrative purposes, solder balls 30 are illustrated in FIGS. 1 and 2. However, other conventional securing means may be used to secure the single packaged integrated device 16 to the flexible circuit 14 and should not be limited to the configuration shown.

In accordance with one embodiment, the flexible circuit 14 includes an indenture 32 (e.g., a living hinge) configured for permitting the flexible circuit 14 to bend at an angle, which may vary depending on the application, such that one end of the flexible circuit 14 is substantially parallel to a planar surface 40 of the carrier package 12 while the other end is elevated at an angle with respect to the planar surface 40 of the carrier package 12. In one embodiment, the indenture 32 has a cross-sectional thickness less than the cross-sectional thickness of the remaining portions of the flexible circuit 14 as shown. In accordance with one embodiment, a portion of the bottom surface 22 of the flexible circuit 14 includes interconnects 42 configured for electrically coupling to the carrier package 12 having conductive circuit traces formed along its planar surface 40. Thus, the integrated devices 16 of each assembly can be serially connected via the carrier package 12. It is contemplated that the interconnects 28 are separate from the flexible circuit 14 and disposed between a portion of the bottom surface 22 of the flexible circuit 14 and the planar surface 40 of the carrier package 12.

In accordance with one embodiment, the assemblies 18 are stacked on top of one another in a semi-stacking configuration. In other words, the assemblies 18 are stacked like shingles, similar to shingles overlapping and stacking on a rooftop. The assemblies 18 are configured to stack in such a configuration by bending the flexible circuit 14 of each assembly 18 via the indenture 32 of the flexible circuit 14 and overlapping the integrated devices on the next level (atop the integrated device of another assembly) as shown in FIG. 1. In one example, the interconnects 42 located on one end of one of the flexible circuits 14 correspondingly having one of the integrated devices 16 mounted therewith is coupled to a portion of the planar surface 40 of the carrier package 12 while the opposite end of the flexible circuit 14 is elevated at an angle with respect to the planar surface 40 of the carrier package 12 and overlaid over a top surface portion of one of the integrated devices of another assembly and one end of the flexible circuit of that assembly is overlaid over a top surface portion of another one of the integrated devices of yet another assembly, and so forth as shown in FIG. 1. In this configuration, one side of the flexible circuit of each assembly is elevated at an angle, thus effectively elevating the integrated device 16 of each assembly at the same angle in which its respective flexible circuit is elevated. Consequently, a small portion of each integrated device of an assembly is not covered and is freely exposed for efficient cooling.

The relative placement of interconnects of each flexible circuit of each assembly and the angle of each overlapping integrated device can vary depending on the application and design requirements. Advantageously, the overlapping of the integrated devices 16 utilizing flexible circuits permits a tighter pitch layout on the carrier package 12. Thus, a larger number of integrated devices can be assembled over a smaller area of the carrier package 12. In sum, this configuration permits removal of heat from each of the integrated devices 16 in an efficient manner while maximizing space over the carrier package 12.

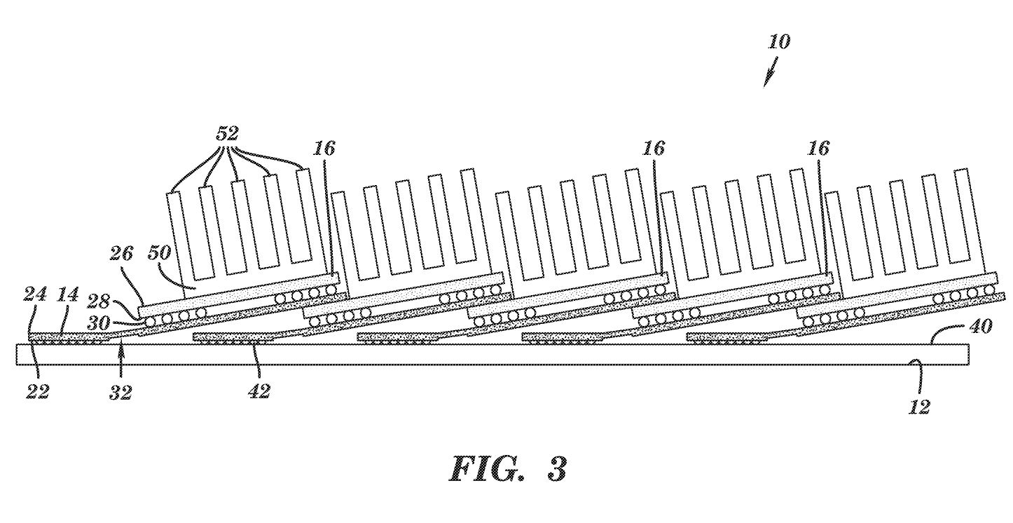

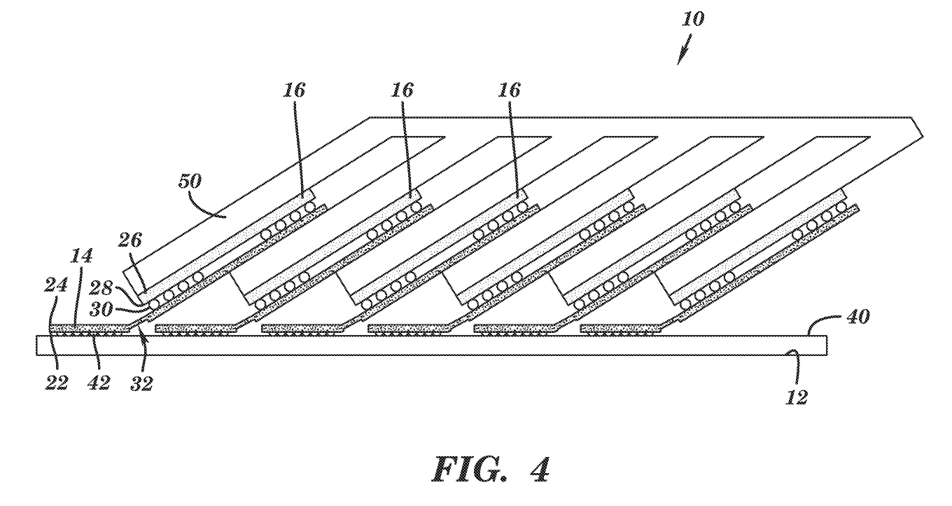

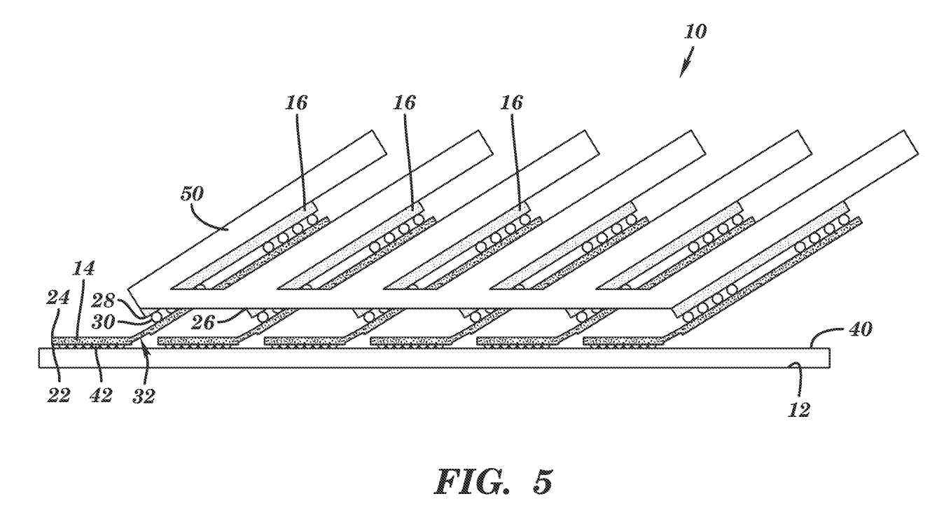

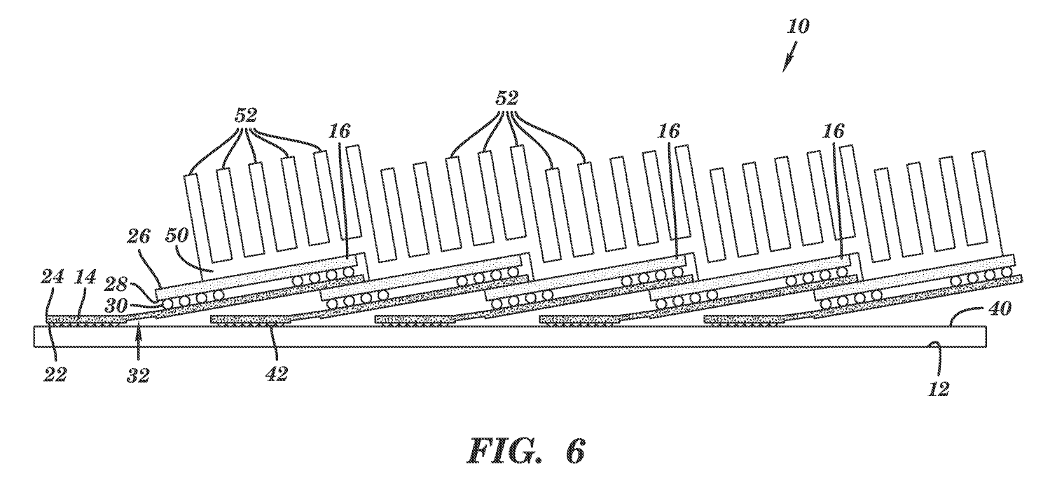

In one exemplary embodiment, a heat sink device 50 having heat sink fins 52 is mounted on each of the integrated devices 16 of each assembly 18 as shown in FIG. 3. It is contemplated that the heat sink fins 52 of the individual heat sink devices 50 correspondingly mounted on the integrated devices 16 of each assembly are tied together above the components (e.g., flexible circuit) as shown in FIG. 4 or at the side of the components as shown in FIG. 5, thus serially connecting the heat sink devices 50 of each integrated device 16. In one non-limiting exemplary embodiment, the heat sink device 50 is a single continuous heat sink commonly mounted on the integrated devices 16 as shown in FIG. 6. The heat sink device 50 for each of the integrated devices 16 is configured to provide an airflow medium through which the same can cool more rapidly or redirect heat into the atmosphere.

In accordance with one embodiment, the heat sink device 50 (continuous or individual) is mounted on the integrated device(s) through the use of an adhesive thermal interface material, such as, for example, glue. Of course, other means for securing the heat sink device on the integrated device can be used and should not be limited to the example set forth above.

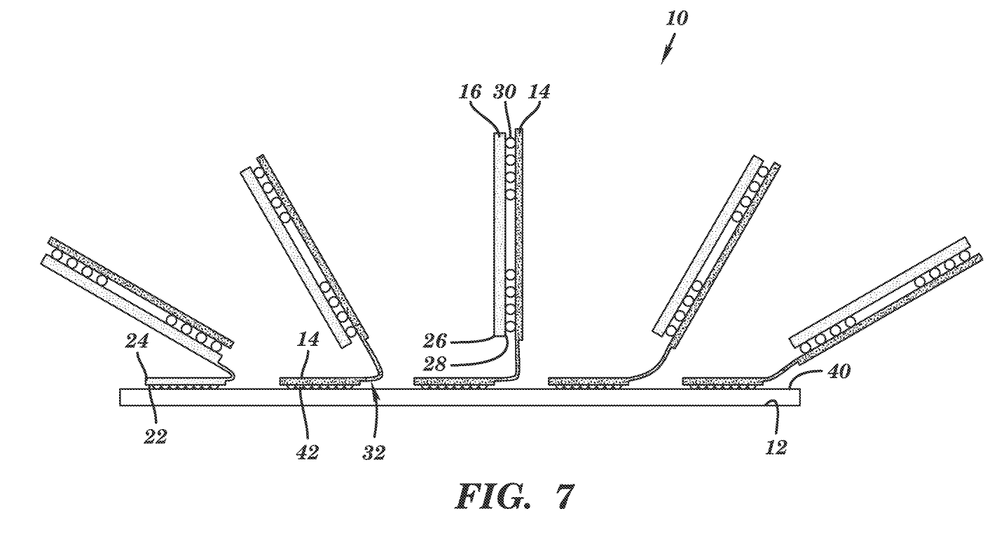

The heat sink configuration may vary depending on the system layout and airflow means. For example, the flexible circuits 14 of each assembly may have their respective integrated devices 16 at right angles or beyond right angles (e.g., 90-degree angle) with respect to the carrier 12 or a combination of both. FIG. 7 illustrates the flexible circuits 16 bent at different angles within the same design to fit a particular system layout in accordance with one exemplary embodiment. It should be understood that the flexible circuits 14 could be bent to sharper angles, thus obtaining an even tighter pitch design layout.

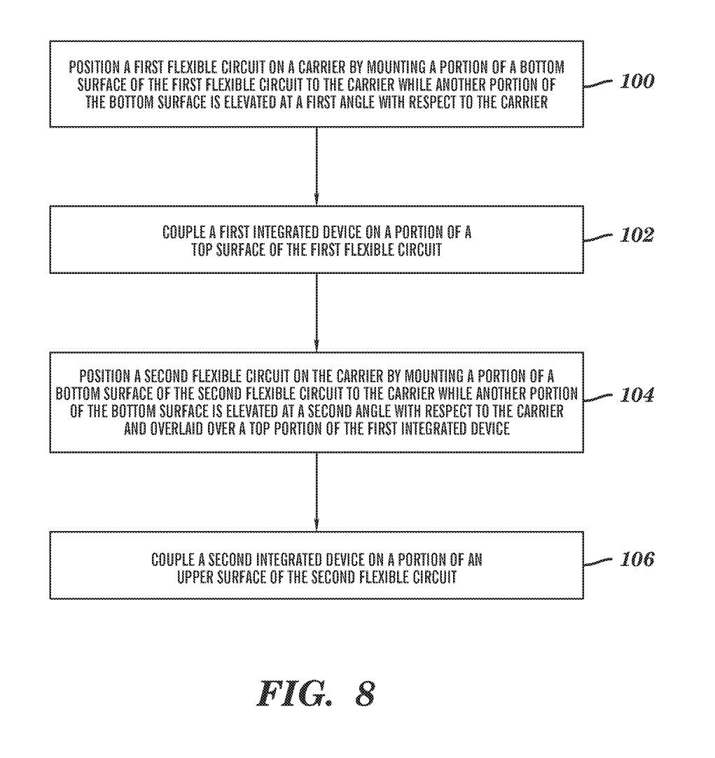

In accordance with an exemplary embodiment of the present invention, an exemplary method for connecting a series of integrated devices utilizing flexible circuits in a semi-stacking configuration is provided and illustrated in FIG. 8. In this exemplary method, position a first flexible circuit on a carrier by mounting a portion of a bottom surface of the first flexible circuit to the carrier while another portion of the bottom surface is elevated at a first angle with respect to the carrier in block 100. Then, couple a first integrated device on a portion of a top surface of the first flexible circuit in block 102. In accordance with one embodiment, the first integrated device is effectively elevated at the first angle. Next, position a second flexible circuit on the carrier by mounting a portion of a bottom surface of the second flexible circuit to the carrier while another portion of the bottom surface is elevated at a second angle with respect to the carrier and overlaid over a top portion of the first integrated device in block 104. In block 106, couple a second integrated device on a portion of an upper surface of the second flexible circuit. In accordance with one embodiment, the second integrated device is effectively elevated at the second angle. This method can continue with a third flexible circuit, fourth flexible circuit, and so on using the configuration as described above. As a result, a semi-stacking configuration is realized, which facilitates efficient removal of heat from the integrated devices.

The capabilities of the present invention can be implemented in software, firmware, hardware or some combination thereof.

As one example, one or more aspects of the present invention can be included in an article of manufacture (e.g., one or more computer program products) having, for instance, computer usable media. The media has embodied therein, for instance, computer readable program code means for providing and facilitating the capabilities of the present invention. The article of manufacture can be included as a part of a computer system or sold separately.

Additionally, at least one program storage device readable by a machine, tangibly embodying at least one program of instructions executable by the machine to perform the capabilities of the present invention can be provided.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method of connecting a series of integrated devices utilizing flexible circuits in a semi-stacking configuration, the method comprising:
positioning a first flexible circuit on a carrier, the first flexible circuit including a bottom surface and a top surface, a portion of the bottom surface mounted to the carrier while another portion of the bottom surface is elevated at a first angle with respect to the carrier;
coupling a first integrated device on a portion of the top surface of the first flexible circuit, the first integrated device being elevated at the first angle;
positioning a second flexible circuit on the carrier, the second flexible circuit having an upper surface and a lower surface, a portion of the lower surface is mounted to the carrier while another portion of the lower surface is elevated at a second angle with respect to the carrier and overlaid over a top surface portion of the first integrated device; and
coupling a second integrated device on a portion of the upper surface of the second flexible circuit, the second integrated device being elevated at the second angle.

2. The method as in claim 1, wherein the first flexible circuit includes a first indenture configured for facilitating the first flexible circuit to bend at the first angle.

3. The method as in claim 1, wherein the second flexible circuit includes a second indenture configured for facilitating the second flexible circuit to bend at the second angle.

4. The method as in claim 1, further comprising mounting a heat sink device atop the first integrated device and the second integrated device.

5. The method as in claim 1, further comprising mounting a continuous heat sink device atop the first integrated device and the second integrated device, the continuous heat sink device having a plurality of fins serially coupled together.
